(19) United States
(12) Patent Application Publication
(10) Pub. No.: US 2026/0103588 A1
(43) Pub. Date: Apr. 16, 2026

(54) FLAME-RETARDANT PLASTIC MATERIAL AND HOME APPLIANCE INCLUDING THE SAME

(71) Applicant: SAMSUNG ELECTRONICS CO., LTD., Suwon-si (KR)

(72) Inventors: Miran KIM, Suwon-si (KR); Nohcheol PARK, Suwon-si (KR); Jongun CHOI, Suwon-si (KR); Yunshik YANG, Suwon-si (KR); Sungjoon YOON, Suwon-si (KR)

(73) Assignee: SAMSUNG ELECTRONICS CO., LTD., Suwon-si (KR)

(21) Appl. No.: 19/342,832

(22) Filed: Sep. 29, 2025

Related U.S. Application Data
(63) Continuation of application No. PCT/KR2025/013275, filed on Aug. 29, 2025.

(30) Foreign Application Priority Data
Oct. 16, 2024 (KR) 10-2024-0141498

(51) Int. Cl. C08L 23/12; C08K 3/22; C08K 3/32; C08K 7/14; D06F 23/02; D06F 34/28; D06F 39/12; F25D 23/06; H05K 5/00

(52) U.S. Cl. CPC C08L 23/12; C08K 3/22; C08K 3/32; C08K 7/14; D06F 23/02; D06F 34/28; D06F 39/12; F25D 23/065; C08K 2003/2296; C08K 2003/329; C08K 2201/003; C08K 2201/004; C08K 2201/014; C08L 2201/02; C08L 2203/20; C08L 2205/025; C08L 2207/20; H05K 5/0026

(57) ABSTRACT

A home appliance may include: a main body forming an exterior; and a control panel connected to the main body, and including a printed circuit board and a panel housing surrounding the printed circuit board wherein the panel housing may include a flame-retardant plastic composition including: a polypropylene-based resin, a recycled plastic resin, a flame retardant including a compound including phosphorus and nitrogen and further including at least one compound from among compounds including pyrophoric acid, or zinc oxide, and glass fiber.

### CROSS-REFERENCE TO RELATED APPLICATIONS

This application is a continuation of International Application No. PCT/KR2025/013275 designating the United States, filed on Aug. 29, 2025, in the Korean Intellectual Property Receiving Office and claiming priority to Korean Patent Application No. 10-2024-0141498, filed on Oct. 16, 2024, in the Korean Intellectual Property Office, the disclosures of each of which are incorporated by reference herein in their entireties.

### TECHNICAL FIELD

An embodiment of the disclosure relates to a flame-retardant plastic material, and more specifically, to a flame-retardant plastic material for a housing included in a home appliance.

### BACKGROUND ART

To prevent the risk of fire in home appliances and to restrict its spread when a component within the appliance ignites, both internal and external components of home appliances may be constructed from flame-retardant materials. To prevent the spread of fire, flame-retardant materials may be applied to both the interior and exterior of the home appliance, including the casing that surrounds the printed circuit board (PCB).

To prevent the spread of fire, multiple components of home appliances may be fabricated by bending metal materials such as iron plates; however, this approach may lead to increased process complexity and higher production costs. To prevent the spread of fire in home appliances, integrated components using flame-retardant plastic materials may be applied.

Meanwhile, the recent tightening of international environmental regulations may restrict the use of halogen-based flame retardants, such as bromine (Br) flame retardants, as flame-retardant materials. This is due to the generation of substances harmful to both the human body and the environment, such as dioxin and furan, which may occur when halogen-based flame-retardant plastic materials are burned. Consequently, the cost burden and scope of manufacturing products that include harmful substances may be increasing. Therefore, to reduce harmful substances, a flame retardant material may be formulated using phosphorus- or nitrogen-based compounds. Flame-retardant materials may reduce exterior damage and limit the release of harmful substances during a fire by employing materials with high flame retardancy and increased durability against flames when ignited.

The above-described information may be provided as related art for the purpose of helping understanding of the disclosure. No claim or determination is made as to whether any of the foregoing is applicable as background art in relation to the disclosure.

### DISCLOSURE OF INVENTION

### Technical Problem

The flame-retardant plastic material according to an embodiment of the disclosure may include a phosphorus/nitrogen-based compound, provide a flame-retardant function of a predetermined level or higher, and may be composed of a compound having a fire-resistant property of a predetermined level or higher.

### Technical Solution

In accordance with the present disclosure, a home appliance may include: a main body forming an exterior; and a control panel connected to the main body, and including a printed circuit board and a panel housing surrounding at least a portion of the printed circuit board wherein the panel housing includes a flame-retardant plastic composition including a polypropylene-based resin, a recycled plastic resin, a flame retardant including a compound including phosphorus and nitrogen and further including at least one compound from among compounds including pyrophoric acid, or zinc oxide, and glass fiber.

The compound including phosphorus and nitrogen may further include at least one compound from among compounds including piperazine pyrophosphate, melamine polyphosphate, ammonium polyphosphate, and alkylamine phosphate.

The flame-retardant plastic composition may further include 25 wt % to 35 wt % of the compound including phosphorus and nitrogen relative to a total weight of the flame-retardant plastic composition.

The flame retardant may further include 5 wt % to 10 wt % of a combination of the pyrophoric acid and the zinc oxide relative to a total weight of the flame retardant.

The flame-retardant plastic composition may further include 5 wt % to 15 wt % of the glass fiber relative to a total weight of the flame-retardant plastic composition.

The glass fiber may include fibers having an average particle diameter of 5 μm (micrometer) to 15 μm and an average length of 1 mm to 16 mm.

The flame-retardant plastic composition may further include 35 wt % to 55 wt % of the polypropylene-based resin relative to a total weight of the flame-retardant plastic composition, and the polypropylene-based resin may include at least one polymer from among polymers including a propylene homopolymer, an ethylene-propylene random copolymer, and an ethylene-propylene block copolymer.

The polypropylene-based resin may have a melt flow index of 5 g/10 min to 50 g/10 min.

The recycled plastic resin may include recycled polypropylene and recycled polyethylene, and the flame-retardant plastic composition may further include 10 wt % to 20 wt % of the recycled plastic resin relative to a total weight of the flame-retardant plastic composition.

The recycled plastic resin may further include a composition ratio of the recycled polypropylene to the recycled polyethylene of 1:0.05 to 1:0.2.

The flame-retardant plastic composition may have a shrinkage rate of 0.3% to 0.8%.

The flame-retardant plastic composition may have an Izod notch impact strength of 4.0 kgf·cm/cm to 4.5 kgf·cm/cm.

The flame-retardant plastic composition may have a flexural modulus of 20,000 kgf/cm² to 27,000 kgf/cm².

The flame-retardant plastic composition may have a tensile strength of 240 kgf/cm² to 280 kgf/cm².

The flame-retardant plastic composition may have a melt flow index of 5 g/min to 10 g/min.

In accordance with the present disclosure, a washer may include: a main body including an inlet configured to receive laundry; a rotatable drum inside the main body; a door configured to open and close the inlet; and a control assembly connected to the main body and including a control board, the control board including a printed circuit board and a control housing surrounding at least a portion of the control board, wherein the control housing may include a flame-retardant plastic composition including: a polypropylene-based resin, a recycled plastic resin, a flame retardant including a compound including phosphorus and nitrogen and further including at least one compound from among compounds including pyrophoric acid, or zinc oxide, and glass fiber.

The compound including phosphorus and nitrogen may further include at least one compound from among compounds including piperazine pyrophosphate, melamine polyphosphate, ammonium polyphosphate, and alkylamine phosphate.

The flame-retardant plastic composition may further include 25 wt % to 35 wt % of the compound including phosphorus and nitrogen relative to a total weight of the flame-retardant plastic composition.

The flame retardant may further include 5 wt % to 10 wt % of a combination of the pyrophoric acid and the zinc oxide relative to a total weight of the flame retardant.

The flame-retardant plastic composition may further include 5 wt % to 20 wt % of the glass fiber relative to a total weight of the flame-retardant plastic composition.

The glass fiber may include fibers having an average diameter of 5 μm (micrometer) to 15 μm and an average length of 1 mm to 16 mm.

The disclosure is not limited to the foregoing embodiments but various modifications or changes may rather be made thereto without departing from the spirit and scope of the disclosure.

The flame-retardant plastic material according to an embodiment of the disclosure has a predetermined level of flame-retardant and fire-resistant properties, reducing the spread of fire when the fire occurs.

Since the flame-retardant plastic material according to an embodiment of the disclosure does not include a halogen-based material, it may limit generation of harmful gases during combustion.

The flame-retardant plastic material according to an embodiment of the disclosure may be manufactured with a low-cost composition, thereby increasing productivity.

### BRIEF DESCRIPTION OF DRAWINGS

FIG. 1 illustrates the appearance of a material after performing flame resistance evaluation on a flame-retardant plastic composition according to an embodiment of the disclosure;

FIG. 2 illustrates the appearance of a material after performing flame resistance evaluation on a flame-retardant plastic composition according to an embodiment of the disclosure;

FIG. 3 illustrates the appearance of a material after performing flame resistance evaluation on a flame-retardant plastic composition according to an embodiment of the disclosure;

FIG. 4 is a perspective view illustrating a washer according to an embodiment of the disclosure;

FIG. 5 is an exploded view illustrating a control panel included in a washer according to an embodiment of the disclosure;

FIG. 6 is an exploded perspective view illustrating a cooking device according to an embodiment of the disclosure;

FIG. 7 is an exploded view illustrating a control panel included in a cooking device according to an embodiment of the disclosure;

FIG. 8 is an exploded perspective view illustrating an indoor unit of an air conditioner according to an embodiment of the disclosure;

FIG. 9 is a perspective view illustrating a refrigerator according to an embodiment of the disclosure; and

FIG. 10 is an exploded perspective view illustrating a panel assembly included in a refrigerator according to an embodiment of the disclosure.

### MODE FOR THE INVENTION

An embodiment of the disclosure and terms used therein are not intended to limit the technical features described in the disclosure to specific embodiments, and should be understood to include various modifications, equivalents, or substitutes of the embodiment. With regard to the description of the drawings, similar reference numerals may be used to refer to similar or related elements. It is to be understood that a singular form of a noun corresponding to an item may include one or more of the things, unless the relevant context clearly indicates otherwise. As used herein, each of such phrases as “A or B,” “at least one of A and B,” “at least one of A or B,” “A, B, or C,” “at least one of A, B, and C,” and “at least one of A, B, or C,” may include all possible combinations of the items enumerated together in a corresponding one of the phrases. As used herein, such terms as “1st” and “2nd,” or “first” and “second” may be used to simply distinguish a corresponding component from another, and does not limit the components in other aspect (e.g., importance or order).

However, in the disclosure, the terms “front and rear direction”, “left and right direction”, and “upper and lower direction” to be used below may be used with respect to the illustrated drawings, and the shape and position of each component are not limited thereto.

According to an embodiment, each component (e.g., a module or a program) of the above-described components may include a single entity or multiple entities. Some of the plurality of entities may be separately disposed in different components.

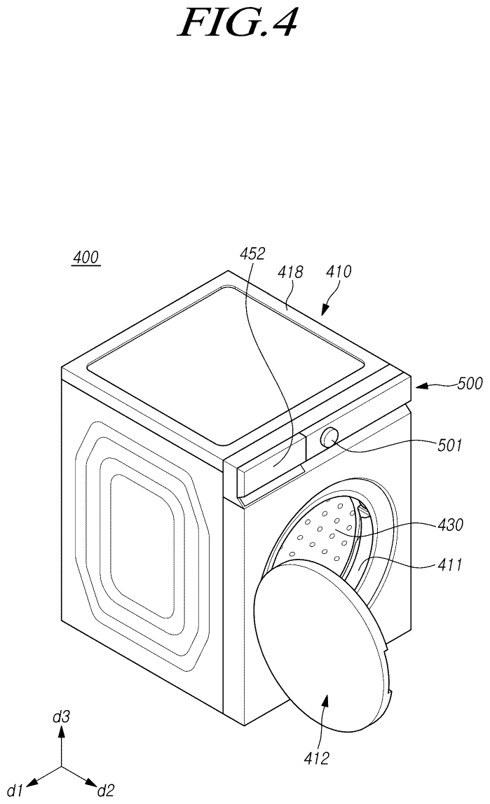

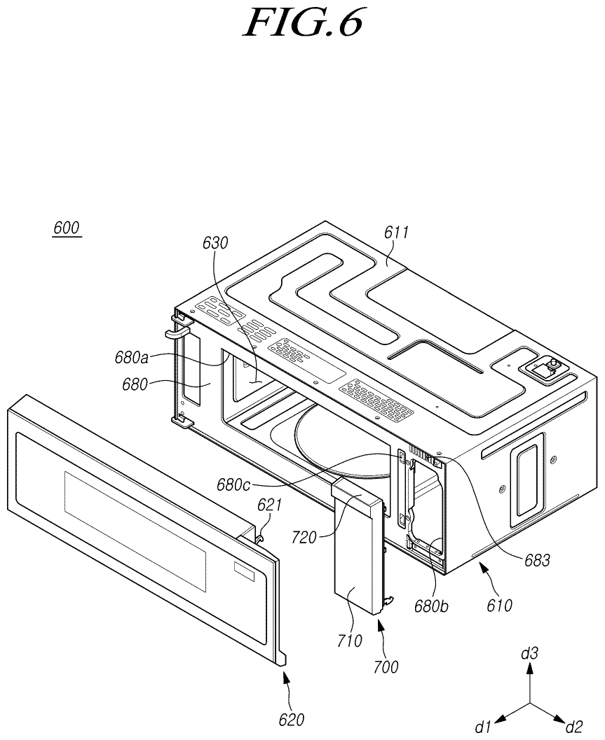

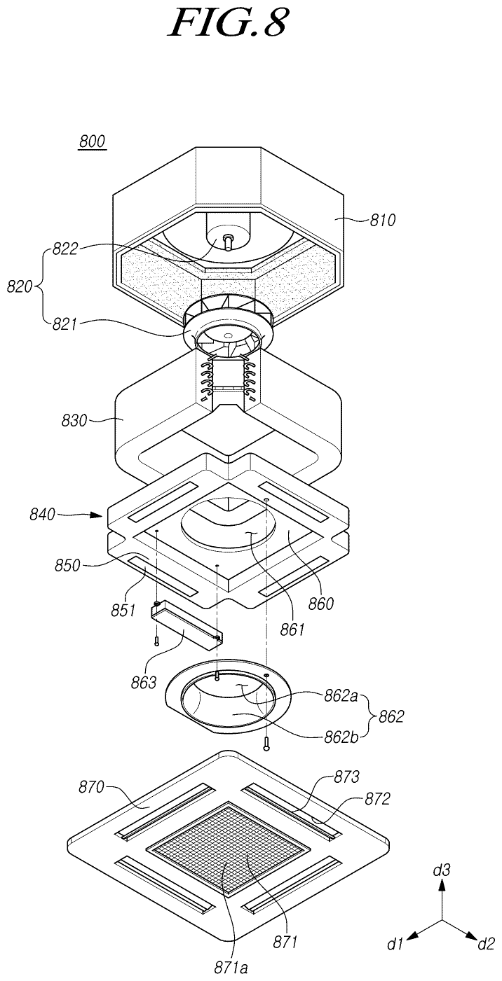

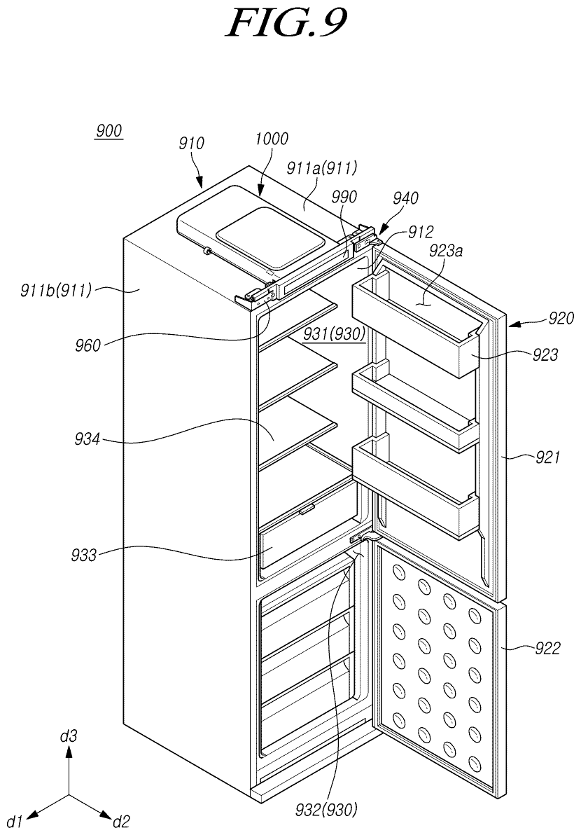

It may be understood that various types of home appliances (e.g., washer 400 of FIG. 4, the cooking device 600 of FIG. 6, the indoor unit 800 of FIG. 8, and the refrigerator 900 of FIG. 9) described below may be understood as illustrative for a better understanding of the disclosure, and various changes may be made thereto. Further, in some of the accompanying drawings, the dimensions of some components may be exaggerated rather than being shown at the actual scale to help understand the disclosure.

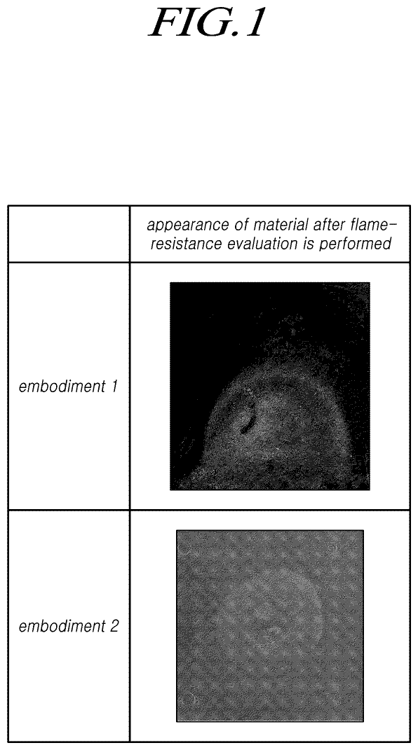

FIG. 1 illustrates the appearance of a material after performing flame resistance evaluation on a flame-retardant plastic composition according to an embodiment of the disclosure.

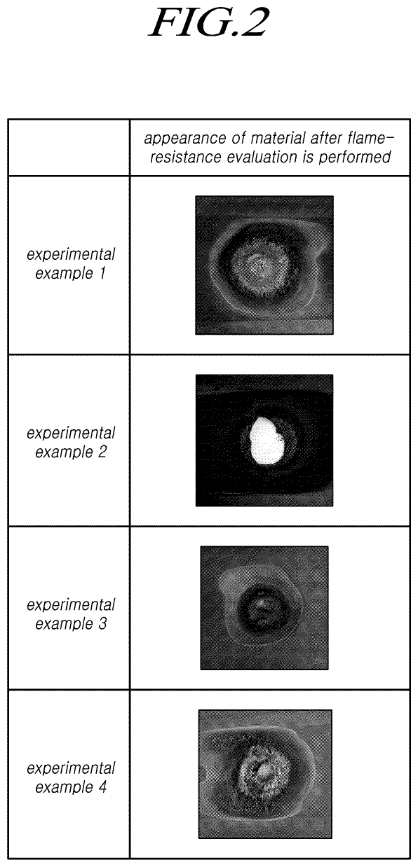

FIG. 2 illustrates the appearance of a material after performing flame resistance evaluation on a flame-retardant plastic composition according to an embodiment of the disclosure.

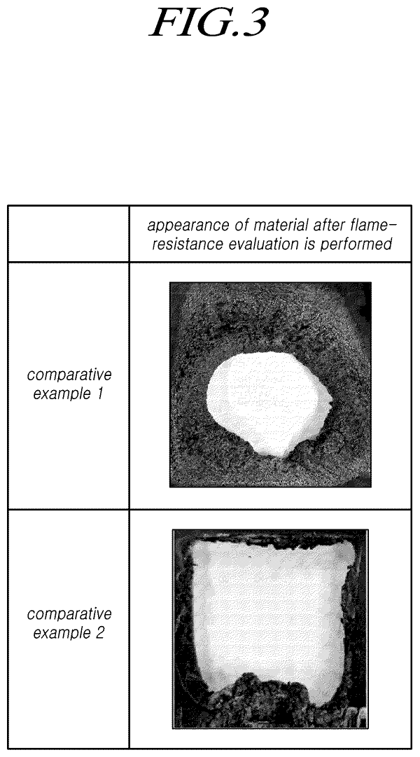

FIG. 3 illustrates the appearance of a material after performing flame resistance evaluation on a flame-retardant plastic composition according to an embodiment of the disclosure.

FIGS. 1 to 3 illustrate the appearance of materials after conducting a flame resistance evaluation on embodiments, experimental examples, and comparative examples of plastic compositions prepared according to the constituent materials and mixing ratios, and may be understood to depict the durability of each plastic composition against flames.

For example, FIG. 1 illustrates the appearance of a material after performing flame resistance evaluation on embodiments 1 and 2 of the disclosure. Embodiments 1 and 2 may be understood as flame-retardant plastic compositions having flame retardancy and flame resistance of the disclosure.

For example, FIG. 2 illustrates the appearance of a material after performing flame resistance evaluation on experimental example 1, experimental example 2, experimental example 3, and experimental example 4 of the disclosure. Experimental embodiments 1 to 4 may be prepared by changing the composition ratio of the main constituent materials compared to embodiments 1 and 2. Experimental embodiments 1 to 4 may be understood as plastic compositions in which at least one of flame retardancy and flame resistance is not secured.

For example, FIG. 3 illustrates the appearance of a material after performing flame resistance evaluation on comparative example 1 and comparative example 2 of the disclosure. Comparative example 1 and comparative example 2 may be prepared by changing the ratio of the main constituent materials and/or the main constituent materials compared to Embodiments 1 and 2. Comparative examples 1 and 4 may be understood as plastic compositions in which at least one of flame retardancy and flame resistance is not secured.

Referring to FIGS. 1 to 3, the flame-retardant plastic composition of the disclosure is a halogen-free composition that does not include halogen materials, and may prevent the generation of harmful substances such as dioxin and/or furan when the composition is burned.

According to an embodiment, the flame-retardant plastic composition of the disclosure has a predetermined level or higher of flame resistance, thereby reducing damage to the exterior and the interior by a flame.

According to an embodiment, the flame-retardant plastic composition of the disclosure is a material applicable to manufacturing components included in home appliances (e.g., the washer 400 of FIG. 4, the cooking device 600 of FIG. 6, the indoor unit 800 of FIG. 8, and the refrigerator 900 of FIG. 9), and may provide a flame-retardant function of a predetermined level or higher that may cause the spread of fire in the event of a fire. For example, the flame-retardant plastic composition of the disclosure may be applied to an exterior housing of a control panel included in the home appliance. When a fire occurs in a printed circuit board (PCB) included in the control panel, the exterior housing formed of the flame-retardant plastic composition may reduce the further spread of fire and damage.

The flame-retardant plastic composition of the disclosure, which is described below, may provide flame retardancy and durability (flame resistance) against flames by mixing the constituent materials at a predetermined composition ratio. Unless otherwise stated, it may be understood that the content of each component is roughly represented relative to the total weight (100 wt %) of the flame-retardant plastic composition in the numerical limitation of the materials constituting the flame-retardant plastic composition.

According to an embodiment, the flame-retardant plastic composition may include a polypropylene-based resin, a phosphorus/nitrogen-based compound, a filler, and other additives composed in a predetermined ratio.

According to an embodiment, the polypropylene-based resin may include one or more of a propylene homopolymer, an ethylene-propylene random copolymer, and/or an ethylene-propylene block copolymer. For example, the polypropylene resin may be composed of any one of a propylene homopolymer, an ethylene-propylene random copolymer, or an ethylene-propylene block copolymer, or a mixture of two or more of a propylene homopolymer, an ethylene-propylene random copolymer, and an ethylene-propylene block copolymer.

According to an embodiment, the polypropylene-based resin may have a predetermined fluidity. For example, the polypropylene-based resin may have a melt flow index (MFI) of 5 to 50 g/10 min at a load of 2.16 kg at 230° C. according to the ASTM D1238 standard.

According to an embodiment, the flame-retardant plastic composition may further include synthetic rubber. The synthetic rubber may be used as an auxiliary resin to enhance the impact strength of the flame-retardant plastic composition. The synthetic rubber may be configured in a predetermined ratio with respect to the composition ratio of the polypropylene-based resin.

According to an embodiment, the synthetic rubber may include one or more of low-density polyethylene (LDPE), linear low-density polyethylene (LLDPE), ethylene-α-olefin copolymer, propylene-α-olefin copolymer, ethylene vinyl acetate (EVA) copolymer, ethylene-methyl acrylate (EMA) copolymer, ethylene-ethyl acrylate (EEA), ethylene-butyl acrylate (EBA), styrene-butadiene-styrene (SBS) rubber, styrene-ethylene-butadiene-styrene (SEBS) copolymer, ethylene-propylene-diene monomer (EPDM) rubber, ethylene glycol dimethacrylate (EDM) rubber, copolymer and polyolefin elastomer (POE). For example, the synthetic rubber may be composed of a single material among the materials applicable to the synthetic rubber, or a mixture of two or more.

According to an embodiment, the polypropylene-based resin may be included in an amount of about 35 to 55 wt % relative to the total weight of the flame-retardant plastic composition.

According to an embodiment, in order to enhance impact strength of the flame-retardant plastic composition, when synthetic rubber is added to the polypropylene-based resin, the synthetic rubber may be included in an amount of about 0.1 to 5 wt % relative to the total weight of the flame-retardant plastic composition.

In one embodiment, the production cost per unit mass of the polypropylene-based resin may be lower than that of a polyester-based resin. Therefore, the production cost of the flame-retardant plastic composition of the disclosure may be lowered, and thus productivity may be enhanced.

According to an embodiment, the flame-retardant plastic material may further include a recycled plastic resin. For example, the recycled plastic resin may be obtained from post-consumer recycled (PCR) plastic that are recycled after consumption.

According to an embodiment, the recycled plastic resin may be configured in an amount of about 10 to 20 wt % relative to the total weight of the flame-retardant plastic composition.

According to an embodiment, the recycled plastic resin may be configured by mixing polypropylene and polyethylene in a predetermined ratio. For example, the configuration ratio of polypropylene and polyethylene may be 1:0.05 to 1:0.2.

According to an embodiment, the phosphorus/nitrogen-based compound may enhance flame retardancy and flame resistance. The phosphorus/nitrogen-based compound may include a phosphorus/nitrogen-based material (e.g., such as a compound that includes phosphorus and nitrogen), and at least one compound from among compounds including: pyrophoric acid, or zinc oxide.

According to an embodiment, the phosphorus/nitrogen-based material may be a compound that includes phosphorus and nitrogen. For example, the compound that includes phosphorus and nitrogen may include at least one of piperazine pyrophosphate (PPAP), melamine polyphosphate (MPP), ammonium polyphosphate, and alkylamine polyphosphate.

According to an embodiment, the piperazine pyrophosphate has a relatively high melting point of 200° C. or higher, maintaining a stable polymer state under high temperature conditions. Due to this, the piperazine pyrophosphate may be robust to high temperature and high humidity conditions.

According to an embodiment, the phosphorus/nitrogen-based compound may further include at least one compound from among compounds including: pyrophoric acid or zinc oxide, thereby limiting generation of smoke when fired. The phosphorus/nitrogen-based compound may further include at least one compound from among compounds including: pyrophoric acid and zinc oxide, thereby accelerating the formation of char during the combustion of the resin when fired.

According to an embodiment, the phosphorus/nitrogen-based compound may further include at least one compound from among compounds including pyrophoric acid, zinc oxide, or both.

According to an embodiment, the pyrophoric acid and the zinc oxide may be included in an amount of 1 to 5 wt % relative to the total weight of the phosphorus/nitrogen-based compound.

According to an embodiment, the hydrolysis of the phosphorus/nitrogen-based compound at a high temperature may be minimized. For example, the piperazine pyrophosphate included in the phosphorus/nitrogen-based compound may have a predetermined waterproof property.

According to an embodiment, the phosphorus/nitrogen-based compound may be included in an amount of about 25 to 35 wt % relative to the total weight of the flame-retardant plastic composition.

According to an embodiment, the filler may include an inorganic material such as glass fiber, talc, wollastonite, calcium carbonate (CaCO3), or magnesium sulfate (MgSO4). For example, the filler may include feldspar powder, barite, mica, gypsum or magnesium oxide (MgO).

According to an embodiment, the filler may enhance flame resistance of the flame-retardant plastic composition. The filler may be added to control the shrinkage rate of the flame-retardant plastic composition.

According to an embodiment, when a glass fiber is used as the filler, the particle size of the glass fiber may be determined considering flame resistance, shrinkage rate, and/or other physical properties of the flame-retardant plastic composition. For example, the average particle diameter of the glass fiber included in the flame-retardant plastic composition may be 5 to 15 μm (micrometer), and the average length of the glass fiber may be 1 to 16 mm (millimeter). Since the cost of glass fiber having the particle size is relatively low, the production cost required to produce the flame-retardant plastic composition may be decreased, and productivity may be increased.

According to an embodiment, the glass fiber may be obtained from glass roving, glass chopped strand, and glass milled fiber. For example, the glass fiber may be a glass fiber with an average particle diameter of 5 to 15 μm (micrometer) and an average length of 1 to 16 mm among the glass roving, glass chopped strand, and glass milled fibers.

According to an embodiment, when the glass fiber is used as the filler, the composition ratio of the glass fiber may be determined considering flame resistance, shrinkage rate, and/or other physical properties of the flame-retardant plastic composition. For example, if the composition ratio of the glass fiber is lower with respect to an appropriate ratio, flame resistance may deteriorate. For example, if the composition ratio of the glass fiber is high with respect to the appropriate ratio, flame retardancy may deteriorate.

According to an embodiment, the glass fiber may constitute 5 to 20 wt % of the total weight of the flame-retardant plastic composition.

According to an embodiment, the flame-retardant plastic composition may further include other additives for enhancing physical properties. For example, the other additives may include a heat-resistant stabilizer, a weather-resistant stabilizer, an antistatic agent, a lubricant, a slip agent, a nucleating agent, a pigment, and a dye.

According to an embodiment, the other additives may constitute 0.1 to 3 wt % relative to the total weight of the flame-retardant plastic composition.

By controlling the composition components of the flame-retardant plastic composition as described above, the flame-retardant plastic composition according to an embodiment of the disclosure may implement the following physical properties.

According to an embodiment, the flame-retardant plastic composition may have a predetermined level of flame retardancy. For example, the flame-retardant plastic composition may have a predetermined level or higher of flame retardancy based on a vertical combustion test and a flat plate combustion test. For example, the flame retardancy may be measured based on the criteria of passing the bar test and the plaque test in accordance with UL94. For example, the flame-retardant plastic composition may be a composition that has passed the Bar test and the plaque test. For example, the flame-retardant plastic composition may have a flame retardant grade of 1.5T 5VA or higher.

According to an embodiment, the flame-retardant plastic composition may have a predetermined impact strength. The impact strength may be measured at room temperature using a specimen of 3.2T according to the ASTM D256 standard. For example, the impact strength of the flame-retardant plastic composition may be about 1 to 10 kgf·cm/cm. For example, the impact strength may be about 4 to 10 kgf·cm/cm. For example, when the impact strength of the flame-retardant plastic composition is low, cracks may occur in the appearance when applied to home appliances. For example, when the impact strength of the flame-retardant plastic composition is too high, productivity may decrease due to a decrease in fluidity.

According to an embodiment, the flame-retardant plastic composition may have a predetermined tensile strength. For example, the tensile strength may be measured at room temperature at a rate of 50 mm/min according to the ASTM D638 standard. For example, the flame-retardant plastic composition may have a tensile strength of about 150 to 600 kgf/cm2. For example, the tensile strength may be about 240 to 280 kgf/cm2. For example, when the tensile strength of the flame-retardant plastic composition is low, deformation or cracks may occur during the home appliance assembly process. For example, when the tensile strength of the flame-retardant plastic composition is too high, fluidity may be deteriorated and productivity may decrease.

According to an embodiment, the flame-retardant plastic composition may have a predetermined flexural modulus. For example, the flexural modulus may be measured at room temperature at a rate of 2.8 mm/min according to ASTM D790 standard. For example, the flexural modulus of the flame-retardant plastic composition may be about 16,000 to 50,000 kgf/cm2. For example, the flexural modulus may be about 20,000 to 27,000 kgf/cm2.

According to an embodiment, the flame-retardant plastic composition may have a predetermined melt flow index (MFI). For example, the melt flow index may be measured under the condition of 230° C. 2.16 kg according to the ASTM D1238 standard. For example, the melt flow index of the flame-retardant plastic composition may be about 5.0 to 10.0 g/10 min at 230° C. and 2.16 kg loads. For example, when the melt flow index of the flame-retardant plastic material is low, injection molding may be difficult. For example, when the melt flow index of the flame-retardant plastic material is high, tensile strength and impact strength may deteriorate.

According to an embodiment, the flame-retardant plastic composition may have a predetermined shrinkage rate. The shrinkage rate may be understood as the degree to which the volume contracts before and after solidification when the injection-molded material solidifies in the process of manufacturing the injection-molded material constituting the flame-retardant plastic composition by a molding device. For example, the shrinkage rate of the flame-retardant plastic composition may be 0.3 to 0.8%.

According to an embodiment, the flame-retardant plastic composition has substantially the same shrinkage rate as flame-retardant acrylonitrile butadiene styrene (ABS) plastic or high impact polystyrene (HIPS), allowing the same manufacturing device to be used without changing the existing manufacturing device (e.g., molding device) and enhancing productivity.

A method for manufacturing a flame-retardant plastic composition according to an embodiment of the disclosure may manufacture it by mixing materials (e.g., precursors) included in the flame-retardant plastic composition. The manufacturing method may include, e.g., the step of mixing the polypropylene-based resin, phosphorus/nitrogen-based compound, filler, and other additives included in the flame-retardant plastic composition, and extruding the mixture.

According to an embodiment, the step of mixing the precursors is not particularly limited, but a mechanical shear method of kneading each precursor using a twin screw extruder may be used. For example, the extrusion step may be performed at about 180 to 230° C. For example, when the performance temperature of the extrusion step is low, the manufacturing process may be delayed and productivity may be lowered. For example, if the performance temperature of the extrusion step is too high, magnesium hydroxide is highly likely to be decomposed. Considering this, the extrusion step may be performed at about 180 to 230° C.

Referring to FIGS. 1 to 3, the surface appearance state after flame resistance evaluation on the constituent materials included in the flame-retardant plastic composition and the material manufactured in the composition ratio is illustrated.

For example, FIG. 1 illustrates the surface appearance state after flame resistance evaluation on plastics formed according to the mixing ratio of embodiment 1 and embodiment 2, FIG. 2 illustrates the surface appearance state after flame resistance evaluation on plastics formed according to the mixing ratio of experimental example 1, experimental example 2, experimental example 3, and experimental example 4, and FIG. 3 illustrates the surface appearance state after flame resistance evaluation on plastics formed according to the mixing ratio of comparative example 1 and comparative example 2. Embodiment 1, embodiment 2, experimental example 1, experimental example 2, experimental example 3, experimental example 4, comparative example 1, and comparative example 2 may be prepared as pellets by mixing each component set forth in Table 1 according to the mixing ratio, adding 0.1 parts by weight of an antioxidant, and then extruding at 190 to 230° C. through a conventional twin-screw extruder. A specimen may be defined as being manufactured by drying the pellet at 75° C. for 2 hours and then injecting it at a forming temperature of 190 to 230° C. and a mold temperature of 40 to 80° C. in a small injection machine.

TABLE 1

| | | | | | | | comparative | comparative |
|---|---|---|---|---|---|---|---|---|
| | embodiment 1 | embodiment 2 | embodiment 1 | embodiment 2 | embodiment 3 | embodiment 4 | example 1 | example 2 |
| polypropylene- | 47 | 42 | 52 | 52 | 42 | 37 | 0 | 57 |
| based resin | | | | | | | | |
| flame-retardant | 0 | 0 | 0 | 0 | 0 | 0 | 72 | 0 |
| ABS | | | | | | | | |
| phosphorus/ | 30 | 35 | 25 | 30 | 30 | 30 | 0 | 30 |
| nitrogen-based | | | | | | | | |
| compound | | | | | | | | |
| bromine-based | 0 | 0 | 0 | 0 | 0 | 0 | 25 | 0 |
| compound | | | | | | | | |
| glass fiber | 10 | 10 | 10 | 5 | 15 | 10 | 0 | 0 |
| recycled plastic | 10 | 10 | 10 | 10 | 10 | 20 | 0 | 10 |
| resin | | | | | | | | |
| other additives | 3 | 3 | 3 | 3 | 3 | 3 | 3 | 3 |

According to an embodiment, Table 2 below sets forth the physical properties of the flame-retardant plastic composition, and shows whether the composition passes the flame retardancy evaluation, tensile strength, impact strength, flexural modulus, melt flow index, shrinkage rate, and flame resistance evaluation according to the mixing ratio of the constituent materials in embodiment 1, embodiment 2, experimental example 2, experimental example 3, experimental example 3, comparative example 1, and comparative example 2 of Table 1.

FIGS. 1 to 3 show the surface appearance of the composition according to the mixing ratio of embodiment 1, embodiment 2, experimental example 1, experimental example 2, experimental example 3, experimental example 4, comparative example 1, and comparative example 2 of Table 1 after the flame resistance evaluation. The flame resistance evaluation may be evaluated by whether a hole occurs in the appearance of the specimen and the condition of the appearance when the crater is spaced apart by a distance of 60 mm and the specimen is heated by a flame of 1000° C. or higher for 600 seconds. For example, when a hole occurs in the material under the conditions, it may be defined as failing to pass the flame resistance evaluation.

TABLE 2

| | | | | | | | comparative | comparative |
|---|---|---|---|---|---|---|---|---|
| | embodiment 1 | embodiment 2 | embodiment 1 | embodiment 2 | embodiment 3 | embodiment 4 | example 1 | example 2 |
| flame retardancy | ◯ | ◯ | X | ◯ | X | X | X | ◯ |
| evaluation (◯: pass/ | | | | | | | | |
| X: fail) | | | | | | | | |
| tensile strength | 394 | 374 | 431 | 377 | 432 | 385 | 400 | 220 |
| [kgf/cm²] | | | | | | | | |
| impact strength | 8.3 | 7.3 | 8.9 | 4.3 | 11 | 7.5 | 20 | 5 |
| [kgf · cm/cm] | | | | | | | | |
| flexural modulus | 33,600 | 38,300 | 31,200 | 26,400 | 37,500 | 32,600 | 20,000 | 15,500 |
| [kgf/cm²] | | | | | | | | |
| melt flow index | 7.8 | 6.6 | 10.9 | 9.4 | 6.2 | 10.4 | 4 | 15 |
| [g/10 min] | | | | | | | | |
| shrinkage rate [%] | 0.3-0.7 | 0.3-0.7 | 0.4-0.8 | 0.6-1.0 | 0.2-0.6 | 0.3-0.7 | 0.3-0.7 | 1.0-1.3 |
| flame resistance | ◯ | ◯ | ◯ | X(320 s) | ◯ | ◯ | X(19 s) | X(60 s) |
| evaluation (◯: pass/ | | | | | | | | |
| X: fail) (hole | | | | | | | | |
| formation time) | | | | | | | | |

According to an example, whether the flame retardancy test has passed was marked as ‘O’ when both the 5VA bar and plaque tests are passed based on the UL94 standard. Embodiment 1, embodiment 2, experimental example 2, and comparative example 2 passed the flame retardancy test.

According to an embodiment, whether the flame resistance evaluation has been passed was marked as ‘O’ if no hole was formed in the appearance of the specimen when the specimen was separated by a distance of 60 mm and heated by a flame of 1000° C. or higher for 600 seconds. For example, if the specimen had a hole within 600 seconds, it was marked as ‘X’, and the time (unit: second) when the hole was formed immediately after heating was marked. It may be understood that FIGS. 1 to 3 illustrate the appearance of the materials after the flame resistance evaluation is performed on embodiment 1, embodiment 2, experimental example 2, experimental example 3, experimental example 4, comparative example 1, and comparative example 2.

According to an embodiment, embodiments 1 and 2 passed both the flame retardancy evaluation and the flame resistance evaluation. Embodiments 1 and 2 met suitable physical properties such as tensile strength, flexural modulus, impact strength, melt flow index, and shrinkage rate.

According to an embodiment, experimental example 1 failed to pass the flame retardancy evaluation. In experimental example 1, it was identified that the flame retardancy evaluation was not passed due to the relatively low composition ratio of the phosphorus/nitrogen-based flame retardant.

According to an embodiment, experimental example 2 failed to pass the flame resistance evaluation. For example, in experimental example 2, a hole was formed due to firing when 320 seconds elapsed due to flame. In experimental example 2, it was identified that the composition ratio of the glass fiber was relatively low, and thus the flame resistance evaluation was not passed.

According to an embodiment, experimental example 3 failed to pass the flame retardancy evaluation. It was identified that experimental example 3 failed to pass the flame resistance evaluation due to the relatively high composition ratio of the glass fiber. For example, when the composition ratio of the glass fiber in the flame-retardant plastic composition exceeds a threshold level, the glass fiber may be identified to inhibit flame retardancy by functioning as a wick in the material.

According to an embodiment, through experimental example 2 and experimental example 3, the composition ratio of the glass fiber is 5 to 15 wt % relative to the total weight of the flame-retardant plastic composition, so that the flame-retardant plastic composition may secure flame retardancy and flame resistance.

According to an embodiment, it may be identified that the shrinkage rate of experimental example 2 is relatively high as compared to the shrinkage rates of embodiments 1 and 2, and the shrinkage rate of experimental example 3 is relatively low as compared to the shrinkage rates of embodiments 1 and 2. Accordingly, when the composition ratio of the glass fiber included in the flame-retardant plastic composition is at an appropriate level, a shrinkage rate of a reference level may be secured.

According to an embodiment, experimental example 4 failed to pass the flame retardancy evaluation. For example, when the composition ratio of the recycled plastic resin included in the flame-retardant plastic composition exceeds the threshold level, it may be identified that flame retardancy is impaired. However, without limitations to the illustration, according to the components of the recycled plastic resin and the composition ratio of each component, whether the flame-retardant plastic composition passes the flame retardancy evaluation may be changed.

According to an embodiment, comparative example 1 failed to pass both the flame retardancy evaluation and the flame resistance evaluation. For example, in comparative example 1, a hole was formed due to firing when 19 seconds elapsed due to flames. In comparative example 1, it may be identified that flame-retardant ABS is applied in place of the polypropylene resin included in the flame-retardant plastic composition of the disclosure, and a bromine-based flame retardant is applied in place of the phosphorus/nitrogen-based flame retardant included in the flame-retardant plastic composition, making it vulnerable to flames.

According to an embodiment, comparative example 2 passed the flame retardancy evaluation, but failed to pass the flame resistance evaluation. For example, in comparative example 2, a hole was formed due to firing when 60 seconds elapsed due to flames. As in experimental example 2, it was identified that comparative example 2 failed to pass the flame resistance evaluation due to the relatively low composition ratio of the glass fiber.

According to an embodiment, it may be identified that flame retardancy, flame resistance, and other physical properties of the flame-retardant plastic composition according to the composition materials and composition ratio of Table 2 are varied. Accordingly, the polypropylene-based resin, recycled plastic resin, phosphorus/nitrogen-based compound, filler, and other additives included in the flame-retardant plastic composition of the disclosure should be composed in an appropriate ratio.

Hereinafter, an embodiment in which the flame-retardant plastic composition of the disclosure (e.g., embodiments 1 and 2 of Tables 1 and 2) is applicable to a home appliance (e.g., the washer 400 of FIG. 4, the cooking device 600 of FIG. 6, the indoor unit 800 of FIG. 8, and the refrigerator 900 of FIG. 9) is described below.

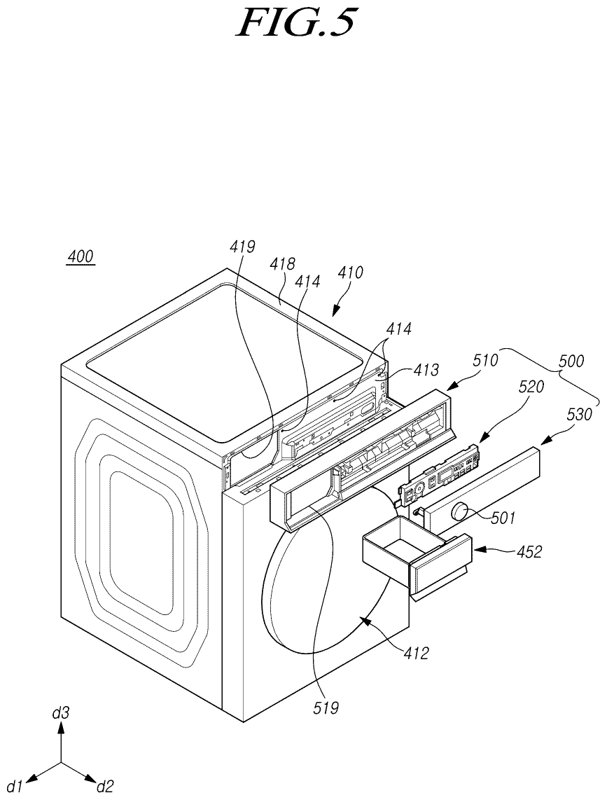

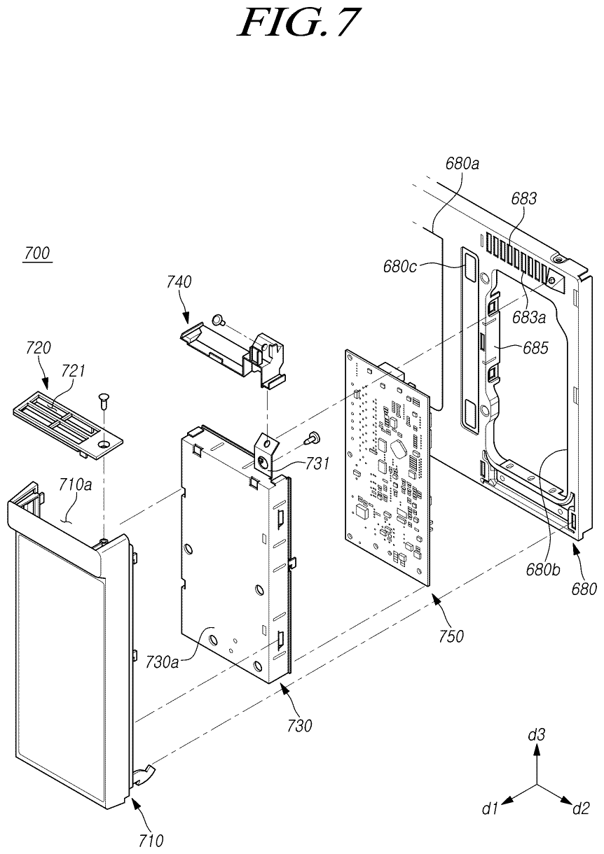

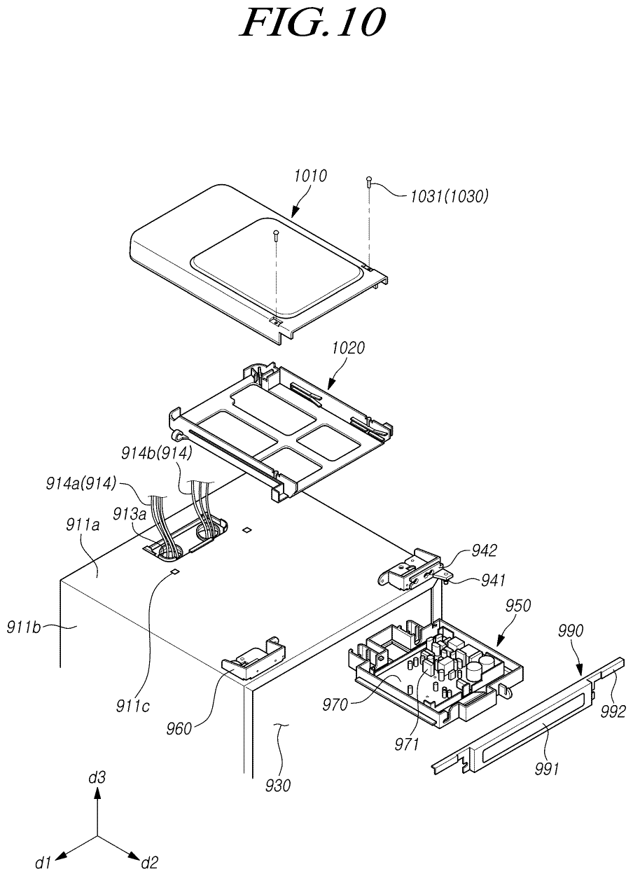

For example, the flame-retardant plastic composition may be applied to a control panel (e.g., the control assembly 500 of FIG. 4, the control box 700 of FIG. 6, and the control box 863 of FIG. 8) including a circuit board (e.g., the control board 520 of FIG. 5, the circuit board 750 of FIG. 7, and the panel assembly 950 of FIG. 10). For example, a housing formed of the flame-retardant plastic composition may constitute a housing surrounding the circuit board 520, 750, 950. Further, the flame-retardant plastic composition may constitute components disposed near the circuit board 520, 750, 950, and the control panel 500, 700, 863.

According to an embodiment, the flame-retardant plastic composition may prevent the fire from spreading to the surroundings when a fire occurs on the circuit board 520, 750, 950.

According to an embodiment, the flame-retardant plastic composition of the disclosure may limit further spread of fire due to the rapid formation of char when fired.

According to an embodiment, since the flame-retardant plastic composition of the disclosure does not include a halogen-based material, generation of harmful gases during combustion may be limited.

According to an embodiment, the flame-retardant plastic composition of the disclosure may achieve eco-friendly management (e.g., ESG management) by including a predetermined proportion of recycled plastic resin.

According to an embodiment, since the flame-retardant plastic composition of the disclosure has substantially the same shrinkage rate as flame-retardant ABS or HIPS, injection-molded products may be prepared using existing manufacturing facilities (e.g., molding devices). As a result, additional costs for manufacturing facilities may be decreased by making injection-molded products formed of the flame-retardant plastic composition using the existing manufacturing facilities.

FIG. 4 is a perspective view illustrating a washer 400 according to an embodiment of the disclosure.

FIG. 5 is an exploded perspective view illustrating a control assembly 500 included in a washer 400 according to an embodiment of the disclosure.

The washer 400 illustrated in FIGS. 4 and 5 may include one or more components formed of the flame-retardant material (e.g., embodiments 1 and 2 of Tables 1 and 2) of the disclosure described in connection with FIGS. 1 to 3.

The embodiments of FIGS. 4 and 5 may be selectively combined with the embodiments of FIGS. 1 to 3.

Referring to FIGS. 4 and 5, a washer 400 may include a main body 410 forming an exterior, a tub disposed inside the main body 410, a drum rotatably disposed inside the tub, and a driving motor driving the drum.

According to an embodiment, the main body 410 may include a front frame 413 forming a front surface. An inlet 411 may be formed in the front frame 413 of the main body 410 to introduce laundry into the drum 430. The inlet 411 may be opened or closed by a door 412 installed on the front of the main body 410.

According to an embodiment, the washer 400 may include a control assembly 500 configured to display the state of the washer 400 to the user or to receive an input for operating the washer 400 from the user. The control assembly 500 may be disposed on the upper portion of the front frame 413 of the main body 410.

According to an embodiment, the control assembly 500 may be provided to be detachable forward from the front frame 413 of the washer 400. The control assembly 500 may include a control housing 510 detachably mounted on the front frame 413, a control panel 530 detachably mounted on the control housing 510, and a control board 520 received between the control housing 510 and the control panel 530.

According to an embodiment, the front frame 413 may include a detergent box passing portion 419 through which the detergent box 452 passes. The control housing 510 may include a detergent box mounting portion 519 on which the detergent box 452 is mounted. The detergent box mounting portion 519 may be provided to correspond to the detergent box passing portion 419.

According to an embodiment, the control housing 510 may be coupled to the front frame 413 along the forward/backward direction. The front frame 413 may include a cabinet fixing portion 414. The control housing 510 may include a housing fixing portion 514 provided to correspond to the cabinet fixing portion 414.

According to an embodiment, the control housing 510 may be fixed to the front frame 413 as the frame fixing member 106 passes through the housing fixing portion 514 and the cabinet fixing portion 414, while the housing fixing portion 514 is positioned on the front frame 413 so that the housing fixing portion 514 is aligned with the cabinet fixing portion 414.

According to an embodiment, the control housing 510 is fixed to the main body 410 through coupling along the forward/backward direction with the main body 410. The control housing 510 is not coupled to the top cover 418 of the main body 410 in the vertical direction. The control housing 510 is not coupled to the front frame 413 of the main body 410 in the vertical direction. Therefore, the control assembly 500 may be separated from the main body 410 even without removing the top cover 418 of the main body 410.

According to an embodiment, the control board 520 may be received between the control housing 510 mounted on the front frame 413 and the control panel 530. The control board 520 may be fixed to the control panel 530. The control panel 530 may include a substrate fixing portion 536 formed on the rear surface to fix the control board 520. The substrate fixing portion 536 may be hooked with a portion of an edge of the control board 520. Alternatively, the control board 520 may be fixed to the control housing 510. The control board 520 may be coupled to the control housing 510 and/or the control panel 530 along the forward/backward direction.

According to an embodiment, the control board 520 may include a printed circuit board (PCB). The control board 520 may be configured to control the washer 400.

According to an embodiment, the control assembly 500 may include a manipulation unit 501 provided to be manipulated by the user. The manipulation unit 501 may be implemented as a knob, a dial button, or a wheel button. The manipulation unit 501 may pass through the control panel 530. The manipulation unit 501 may be disposed to be rotatable about the control panel 530. The manipulation unit 501 may be coupled to the control board 520.

According to an embodiment, the control panel 530 may include a display that displays the operation state or information about the washer 400.

According to an embodiment, at least some components included in the control box 500 may be formed of the flame-retardant plastic of the disclosure (e.g., flame-retardant plastic formed of the flame-retardant plastic compositions of Tables 1 and 2). For example, the control housing 510 and the control panel 530 included in the control box 500 may be formed of the flame-retardant plastic composition. For example, some components included in the control board 520 may be formed of the plastic composition.

According to an embodiment, the components disposed near the control box 500 may be formed of the flame-retardant plastic composition of the disclosure. For example, the front frame 413 and the top cover 418 may be formed of the flame-retardant plastic composition. However, the disclosure is not limited thereto, and at least some of the components formed of plastic among the components included in the washer 400 may be formed of the flame-retardant plastic composition.

According to an embodiment, the control housing 510 and the control panel 530 included in the control box 500 may be formed of the flame-retardant plastic composition.

For example, the control housing 510 and the control panel 530 may be formed of the flame-retardant plastic having a predetermined level of flame retardancy and flame resistance. For this reason, when a fire occurs on the control board 520, it is possible to limit the spread of the fire generated in the control board 520 to the surroundings.

For example, the flame-retardant plastic composition of the disclosure may limit further spread of fire due to the rapid formation of char when fired.

For example, since the flame-retardant plastic composition of the disclosure does not include a halogen-based material, generation of harmful gases during combustion may be restricted.

According to an embodiment, the flame-retardant plastic composition of the disclosure may achieve eco-friendly management (e.g., ESG management) by including a predetermined proportion of recycled plastic resin.

According to an embodiment, since the flame-retardant plastic composition of the disclosure has substantially the same shrinkage rate as flame-retardant ABS or HIPS, injection-molded products may be prepared using existing manufacturing facilities (e.g., molding devices). As a result, additional costs for manufacturing facilities may be decreased by making injection-molded products formed of the flame-retardant plastic composition using the existing manufacturing facilities.

According to an embodiment, since the flame-retardant plastic composition has a predetermined level of flowability in a molten state, productivity may be enhanced when the flame-retardant plastic composition is injected by the molding device.

According to an embodiment, the washer 400 of FIGS. 4 and 5 may be implemented as a dryer or a clothing management device. When the washer 400 of FIGS. 4 and 5 is implemented as a dryer, the dryer may include a heat pump (not illustrated) that supplies dry air into the drum 430. The heat pump may include an evaporator, a condenser, a compressor, and an expansion device. The compressor compresses and discharges the refrigerant at high temperature and high pressure, and the discharged refrigerant may be introduced into the condenser. The condenser condenses the compressed refrigerant and may release heat to the surroundings through a condensation process. The expansion valve may expand the high-temperature and high-pressure refrigerant condensed in the condenser to a low-pressure state. The evaporator may evaporate the expanded refrigerant and remove heat from the surroundings through the evaporation process. For example, the heat pump may further include a heater configured to heat dry air.

According to an embodiment, the heat pump may be mounted on a base positioned at a lower portion of the dryer.

FIG. 6 is a perspective view illustrating a cooking device 600 according to an embodiment of the disclosure.

FIG. 7 is an exploded perspective view illustrating a control box 700 included in a cooking device 600 according to an embodiment of the disclosure.

Some of the components illustrated in FIGS. 6 and 7 may be understood as components included in the cooking device 600 as seen therethrough.

The embodiments of FIGS. 6 and 7 may be selectively combined with the embodiments of FIGS. 1 to 3.

Referring to FIGS. 6 and 7, the cooking device 600 may include a microwave OTR having a hood. Hereinafter, the cooking device 600 is described.

According to an embodiment, the cooking device 600 may include a main body 610 and a door 620 coupled to the front of the main body 610. The cooking device 600 may include a control box 700 that may be detachably mounted on the front of the main body 610.

According to an embodiment, the main body 610 may include an outer housing 611 and an inner housing 612 provided inside the outer housing 611. A cooking chamber 630 and a machine room may be disposed inside the inner housing 612. The cooking chamber 630 and the machine room may be disposed to be partitioned from each other.

According to an embodiment, the door 620 may be provided to open and close the cooking chamber 630. The door 620 may be rotatably coupled to the main body 610. The user may open and close the door 620 through a handle formed between the control box 700 and the door 620. The door 620 may have a recessed portion on the rear side to cover the front side of the control box 700.

According to an embodiment, the cooking device 600 may include a control box 700 that may be detachably mounted on the front of the main body 610. The front side of the control box 700 may be covered by the door 620. More specifically, the control box 700 may be coupled to the main body 610 to be disposed between the door 620 and the main body 610.

According to an embodiment, the main body 610 may include a front plate 680. The front plate 680 may be disposed in front of the cooking chamber 630. The front plate 680 may be disposed in front of the machine room 60. The front plate 680 may include a first opening 680a communicating with the cooking chamber 630 and a second opening 680b communicating with the electric chamber 60. The second opening 680b may be referred to as a front opening 80b.

According to an embodiment, the front plate 680 may include a latch insertion portion 680c into which a latch protrusion 621 of the door 620 is inserted. For example, the latch insertion portion 680c may be provided between the first opening 680a and the second opening 680b. The latch protrusion 621 may be inserted into the main body 610 through the latch insertion portion 680c and locked by a latch body 22. While the latch protrusion 621 is locked to the latch body 22, the door 620 may be maintained in a state of closing the cooking chamber 630.

According to an embodiment, the front plate 680 may include a plate hole 683. The plate hole 683 may communicate with the control box 700. The plate hole 683 may communicate with the machine room 60. The plate hole 683 may guide air introduced from the inlet panel 720 of the control box 700 to the machine room 60. The plate hole 683 may be referred to as a guide hole.

According to an embodiment, the control box 700 may be provided to control the operation of the cooking device 600. The control box 700 may control various electrical components disposed in the machine room.

According to an embodiment, the control box 700 may include a case 710 and an inlet panel 720 coupled to an upper portion of the case 710. The control box 700 may further include a bracket panel 730, a guide member 740, and a circuit board 750.

According to an embodiment, the case 710 may receive the bracket panel 730, the guide member 740, and the circuit board 750. The case 710 may receive the bracket panel 730, the guide member 740, and the circuit board 750. The case 710 may be provided to form the exterior of the control box 700.

According to an embodiment, the case 710 may include an open portion 710a open upward. The inlet panel 720 may be disposed to cover the open portion 710a.

According to an embodiment, the inlet panel 720 may be provided on an upper portion of the case 710. The inlet panel 720 may be provided to cover the open portion 710a. The inlet panel 720 may be provided to cover the guide member 740 and a portion of the main body 610. For example, the inlet panel 720 may prevent the plate hole 683 formed in the front plate 680 from being exposed to the outside.

According to an embodiment, the inlet panel 720 may be detachably coupled to the upper portion of the case 710. For example, the case 710 may be screw-coupled to the inlet panel 720. However, this is merely illustrative, and various coupling methods may be applied. For example, the inlet panel 720 may be integrally formed with the case 710.

According to an embodiment, the inlet panel 720 may communicate with the outside. For example, the inlet panel 720 may include an inlet hole 721 through which air is introduced from the outside to cool the machine room. The inlet hole 721 may be referred to as a first cooling air inlet.

According to an embodiment, the air introduced through the inlet hole 721 may be introduced into the machine room 60 through the plate hole 683 formed in the front plate 680. The plate hole 683 may be referred to as a second cooling air inlet.

According to an embodiment, the air introduced into the machine room may cool the machine room. As a result, the temperature of various electrical components disposed in the machine room may be lowered, and the stability of the electrical components may be increased.

According to an embodiment, the bracket panel 730 may be received in the case 710. The bracket panel 730 may be formed to receive the circuit board 750. For example, the bracket panel 730 may include a shape in which the rear side is open to form a space in which the circuit board 750 is received.

According to an embodiment, a guide member 740 may be detachably coupled to an upper portion of the bracket panel 730. For example, the bracket panel 730 includes a coupling portion 731 extending toward the guide member 740, and the coupling portion 731 may be screw-coupled to the guide member 740. However, this is merely illustrative, and various coupling methods may be applied. For example, the bracket panel 730 may be integrally formed with the guide member 740.

According to an embodiment, the bracket panel 730 may be disposed to be spaced apart from the case 710. For example, the front surface 730a of the bracket panel 730 may be disposed to be spaced apart from the rear surface 110b of the case 710. Accordingly, a space through which moisture may flow may be formed between the bracket panel 730 and the case 710.

According to an embodiment, the guide member 740 may be received in the case 710. The guide member 740 may be disposed under the inlet panel 720. The guide member 740 may be disposed above the bracket panel 730. The guide member 740 may be detachably coupled to an upper portion of the bracket panel 730.

According to an embodiment, the guide member 740 may guide moisture introduced into the control box 700. For example, the guide member 740 may include a shape inclined forward and downward so as to smoothly guide moisture forward.

According to an embodiment, the case 710, the inlet panel 720, the bracket panel 730, and the guide member 740 are illustrated as being provided as separate components and assembled, but are not limited thereto, and the case 710, the inlet panel 720, the bracket panel 730, and the guide member 740 may be integrally formed. For example, only some components of the case 710, the inlet panel 720, the bracket panel 730, or the guide member 740 may be integrally formed.

According to an embodiment, the circuit board 750 may be received in the bracket panel 730. Various electronic components or the like may be mounted on or connected to the circuit board 750. At least a portion of the components received in the main body 610 may be electrically connected to the circuit board 750. For example, the electrical component disposed in the electrical component chamber may be electrically connected to the circuit board 750. For this connection, a front opening 680b may be provided in the front plate 680. Further, access to the inside of the machine room may be possible through the front opening 680b.

According to an embodiment, at least some components included in the control box 700 may be formed of the flame-retardant plastic of the disclosure (e.g., flame-retardant plastic formed of the flame-retardant plastic composition of Tables 1 and 2). For example, at least one of the case 710, inlet panel 720, bracket panel 730, and guide member 740 included in the control box 700 may be formed of the flame-retardant plastic composition. For example, some components included in the circuit board 750 may be formed of the plastic composition.

According to an embodiment, the components disposed near the control box 700 may be formed of the flame-retardant plastic composition of the disclosure. For example, the main body 610 and the door 620 may be formed of the flame-retardant plastic composition.

For example, the case 710, the inlet panel 720, the bracket panel 730, and the guide member 740 may be formed of the flame-retardant plastic having a predetermined level of flame retardancy and flame resistance. For this reason, when a fire occurs on the circuit board 750, it is possible to limit the spread of the fire generated in the circuit board 750 to the surroundings.

For example, the flame-retardant plastic composition of the disclosure may limit further spread of fire due to the rapid formation of char when fired.

For example, since the flame-retardant plastic composition of the disclosure does not include a halogen-based material, generation of harmful gases during combustion may be restricted.

According to an embodiment, the flame-retardant plastic composition of the disclosure may achieve eco-friendly management (e.g., ESG management) by including a predetermined proportion of recycled plastic resin.

According to an embodiment, since the flame-retardant plastic composition of the disclosure has substantially the same shrinkage rate as flame-retardant ABS or HIPS, injection-molded products may be prepared using existing manufacturing facilities (e.g., molding devices). As a result, additional costs for manufacturing facilities may be decreased by making injection-molded products formed of the flame-retardant plastic composition using the existing manufacturing facilities.

According to an embodiment, since the flame-retardant plastic composition has a predetermined level of flowability in a molten state, productivity may be enhanced when the flame-retardant plastic composition is injected by the molding device.

FIG. 8 is an exploded perspective view illustrating an indoor unit 800 included in an air conditioner according to an embodiment of the disclosure.

The embodiment of FIG. 8 may be selectively combined with the embodiment of FIGS. 1 to 3.

Referring to FIG. 8, the air conditioner may be implemented as a multi-type air conditioner that performs a cooling operation and a heating operation. For example, the air conditioner is a device capable of both a cooling operation to cool a plurality of air conditioning spaces and a heating operation to heat a plurality of air conditioning spaces. The air conditioner may include at least one outdoor unit and a plurality of indoor units 800.

According to an embodiment, the outdoor unit may include a compressor, an outdoor heat exchanger, an expansion valve, an outdoor fan, a first detector, a four-way valve, an accumulator, and an oil separator.

According to an embodiment, the compressor may be configured to compress the refrigerant and discharge the compressed high-temperature, high-pressure gaseous refrigerant. For example, during the cooling operation, the compressor may discharge the high-temperature, high-pressure gaseous refrigerant to the outdoor heat exchanger.

According to an embodiment, the outdoor heat exchanger may be configured to perform heat exchange between the refrigerant and outdoor air. For example, during the cooling operation, the outdoor heat exchanger may condense the refrigerant introduced from the compressor through heat dissipation. In this case, the high-temperature, high-pressure gaseous refrigerant may be phase-converted to the high-temperature, high-pressure liquid refrigerant.

According to an embodiment, the expansion valve may include a first expansion valve and a second expansion valve. For example, the first expansion valve and the second expansion valve may distribute the refrigerant supplied from the outdoor heat exchanger through a first distribution pipe and supply the refrigerant to each of the first indoor unit and the second indoor unit. For example, the first expansion valve and the second expansion valve may function as a flow rate control valve capable of adjusting the opening degree in order to control the flow rate of refrigerant supplied to the first and second indoor units. The first expansion valve may be connected between the outdoor heat exchanger and the indoor heat exchanger of the first indoor unit to adjust the flow rate of the refrigerant supplied to the first indoor unit, and the second expansion valve may be connected between the outdoor heat exchanger and the indoor heat exchanger of the second indoor unit to adjust the flow rate of the refrigerant supplied to the second indoor unit.

According to an embodiment, during the cooling operation, the expansion valve may lower the pressure and temperature of the refrigerant introduced from the outdoor heat exchanger. For example, the refrigerant passing through the expansion valve may change from a high-temperature, high-pressure liquid state to a low-temperature, low-pressure liquid state. The expansion operation of the expansion valve may facilitate evaporation of the refrigerant in the heat exchanger of the indoor unit 800. For example, the refrigerant with a decreased pressure and temperature may be transferred to the indoor heat exchanger. For example, the expansion valve may be implemented as a capillary tube.

According to an embodiment, the outdoor fan is provided on one side of the outdoor heat exchanger, and may be configured to forcibly blow air around the outdoor heat exchanger by rotating by a fan motor to assist heat exchange.

According to an embodiment, the first detector may include a first temperature detector for detecting the temperature of the outdoor heat exchanger and a second temperature detector for detecting the outdoor temperature around the outdoor unit. Here, the first temperature detector may be disposed on the output side of the outdoor heat exchanger, on the input side of the outdoor heat exchanger, or in the middle of the outdoor heat exchanger.

According to an embodiment, the outdoor unit may further include a second distribution pipe for collecting refrigerant supplied from each indoor unit 800 and supplying the refrigerant to the compressor.

According to an embodiment, the four-way valve is a flow path switching valve that switches the flow direction of the refrigerant according to the cooling operation or the heating operation. For example, during the heating operation, the four-way valve may guide the high-temperature, high-pressure refrigerant discharged from the compressor to the first and second indoor units, and guide the low-temperature, low-pressure refrigerant of the outdoor heat exchanger to the accumulator. In this case, the outdoor heat exchanger may function as an evaporator, and the first indoor heat exchanger of the first indoor unit and the second indoor heat exchanger of the second indoor unit may function as a condenser.

According to an embodiment, the four-way valve may guide the high-temperature, high-pressure refrigerant discharged from the compressor to the outdoor heat exchanger during the cooling operation and guide the low-temperature, low-pressure refrigerant of the first indoor unit and the second indoor unit to the accumulator. In this case, the outdoor heat exchanger may function as a condenser, and the first indoor unit and the second indoor unit may function as an evaporator.

According to an embodiment, the accumulator may be disposed on the suction side of the compressor to separate the unvaporized liquid refrigerant from the refrigerant introduced into the compressor from the indoor unit 800 to limit the discharge of the liquid refrigerant to the compressor. Thereby, the accumulator may protect the compressor from damage.

According to an embodiment, the oil separator may separate oil mixed in the vapor of the discharge refrigerant of the compressor and recover the separated oil to the compressor. As a result, an oil film is formed on the surface of the outdoor heat exchanger and the indoor heat exchanger, preventing deterioration of the heat transfer effect and deterioration of the lubrication action due to a shortage of lubricant in the compressor.

According to an embodiment, a plurality of indoor units 800 may be provided. When a plurality of indoor units 800 are provided, the indoor units 800 may be disposed in the respective air conditioning space.

According to an embodiment, the air conditioner may further include a connection valve connecting the refrigerant pipe of the outdoor unit to the refrigerant pipes of the first indoor unit and the second indoor unit.

According to an embodiment, the indoor unit 800 may include an indoor heat exchanger 830, a blowing fan 821, an auxiliary fan, and a plurality of temperature detectors.

According to an embodiment, each of the indoor heat exchangers 830 is disposed in the air conditioning space. During the cooling operation, the indoor heat exchanger 830 may be configured to perform heat exchange with air in the air conditioning space through heat absorption by evaporation of the refrigerant introduced from the first and second expansion valves. In this case, the low-temperature, low-pressure liquid refrigerant may be phase-converted to the low-temperature, low-pressure gaseous refrigerant.

According to an embodiment, the blowing fan 821 may be positioned inside the indoor heat exchanger 830. The blowing fan 821 may be rotated by the first motor to suction air in the air conditioning space, and forcibly blow the air heat-exchanged by the indoor heat exchanger 830 into the air conditioning space.

According to an embodiment, the auxiliary fan is positioned inside the indoor heat exchanger 830. The auxiliary fan may adjust the direction of the airflow discharged to the air conditioning space by suctioning some of the air discharged to the air conditioning space by rotating by the second motor.

According to an embodiment, the second detector may include a third temperature detector for detecting the temperature of the refrigerant pipe connected to the inlet of the indoor heat exchanger 830 among the refrigerant pipes connected to the indoor heat exchanger 830, a fourth temperature detector for detecting the temperature of the refrigerant pipe connected to the outlet of the indoor heat exchanger 830 among the refrigerant pipes connected to the indoor heat exchanger 830, and a fifth temperature detector provided inside the indoor unit 800 to detect the temperature of the air conditioning space. Here, the temperature of the inlet and outlet of the indoor heat exchanger 830 detected by the third temperature detector and the fourth temperature detector may be used for superheat control or supercooling control.

According to an embodiment, during the heating operation, the air conditioner may switch the flow path of the four-way valve to guide the high-temperature, high-pressure refrigerant discharged from the compressor to the indoor heat exchanger 830, and guide the low-temperature, low-pressure refrigerant of the indoor unit 800 to the accumulator. In this case, the outdoor heat exchanger may function as an evaporator, and the indoor heat exchanger 830 may function as a condenser.

According to an embodiment, the indoor unit 800 may be installed to be partially introduced into the ceiling 801. The indoor unit 800 may be referred to as a ceiling-mounted air conditioner.

According to an embodiment, the ceiling-mounted air conditioner 801 may include a box-shaped casing 810 introduced into the inside of the ceiling 801, having a blower 820 and a heat exchanger 830, and having a bottom opening, a drain member 840 collecting and discharging the condensate from the heat exchanger 830 to the outside and coupled to a lower portion of the casing 810, and a ceiling panel 870 coupled to the drain member 840 to cover the opening 801a of the ceiling 801.

According to an embodiment, the casing 810 is formed in a substantially hollow container shape to mount the blower 820 and the heat exchanger 830, and an insulation member 811 formed of foamed polystyrene may be attached to the inner surface of the casing 810 for insulation. An adhesive may be used to attach the insulation member 811.

According to an embodiment, the blower 820 disposed at the center to provide forced blowing power and the heat exchanger 830 disposed outside the blower 820 in the radial direction to heat-exchange the air introduced into the casing 810 by the blower 820 may be disposed in the casing 810.

According to an embodiment, the blower 820 includes a blowing fan 821 that suctions air from the bottom and discharges it in a radial direction, and a driving motor 822 that drives the blowing fan 821, and the driving motor 822 may be fixed to the inner upper surface of the casing 810.

According to an embodiment, the heat exchanger 830 may be disposed around the blowing fan 821 to surround the blowing fan 821 to exchange heat with air discharged from the blowing fan 821.

According to an embodiment, the drain member 840 may include a drain tray 850 disposed under the heat exchanger 830 to collect and discharge condensate generated during the heat exchange process, a cold air flow path 851 formed outside the drain tray 850 to guide the heat-exchanged cold air to the discharge portion 872, and a partitioning portion 860 formed inside the drain tray 850 to partition the space inside the casing 810 into a blower area and an outer area.

According to an embodiment, the drain tray 850 supports the lower portion of the heat exchanger 830 and may be formed in a recess shape so that condensate generated on the outer surface of the heat exchanger 830 may flow down and accumulate.

According to an embodiment, the partitioning portion 860 is formed in a flat plate shape having an opening 861 in the center, and the opening 861 of the partitioning portion 860 may be formed to be larger than the outer diameter of the blowing fan 821 so that the blowing fan 821 may pass therethrough. This may be formed to facilitate the easy removal of the blowing fan 821 through the opening 861 when it needs to be detached for repairing the failure of the driving motor 822. For example, the blowing fan 821 may be separated without separating the partitioning portion 860. The partitioning portion 860 may be integrally formed with the drain tray 850, and the partitioning portion 860 and the drain tray 850 may be provided as separate members to couple the edge of the partitioning portion 860 to the inner circumference of the drain member 840.

According to an embodiment, the cold air flow path 851 is formed outside the drain tray 850 at a position corresponding to the discharge portion 872 to communicate with the discharge portion 872 of the ceiling panel 1700 to be described below. Accordingly, the interval in the width direction of the cold air flow path 851 may be formed to have the size equal to or smaller than the interval in the width direction of the discharge portion 872 corresponding thereto.

According to an embodiment, however, the interval in the length direction L of the cold air flow path 81 may be formed to be shorter than the interval in the length direction of the discharge portion 872 of the ceiling panel 870. For example, the drain member 840 installed inside the discharge portion 872 may restrict the exposure of components inside the casing 810 to the outside through the discharge portion 872 by covering the refrigerant pipe and other components (not illustrated) installed inside the ceiling panel 870.

According to an embodiment, a bell mouse member 862 may be disposed at a lower portion of the partitioning portion 860. The bell mouse member 862 may form an opening 862a at the center through which suctioned air passes and an air guide surface 862b formed in a curved shape toward the opening 862a. The bell mouse member 862 may have a circumferential portion detachably coupled to the opening 861 of the partitioning portion 860. The bell mouse member 862 may guide the air introduced through the inlet 871 of the ceiling panel 870 to the suction side of the blowing fan 821.

According to an embodiment, the lower surface of the drain member 840 may be supported by the upper surface of the ceiling panel 870. For example, the ceiling panel 870 may be coupled to the drain member 840 in a state in which the bell mouse member 862 and the control box 863 are coupled to the drain member 840.

According to an embodiment, the ceiling panel 870 may have an inlet 871 for suctioning indoor air at the center thereof, and a plurality of discharge portions 872 may be formed outside the inlet 871. The plurality of discharge portions 872 may be formed at positions corresponding to the cold air flow path 851 of the drain member 840.

According to an embodiment, a filter 871 for filtering air introduced into the inlet 871 may be disposed at the inlet 871 of the ceiling panel 870. For example, each discharge portion 872 may be provided with a blade 873 that guides the discharged air while rotating along a predetermined section. The blade 873 may be operated by a motor rotating in the forward and reverse directions.

According to an embodiment, the discharge portion 872 may be formed in the same shape at four locations in all directions of the ceiling panel 870. The discharge portion 872 may be provided in the form of a channel extending in the length direction, the width direction, and the thickness direction so as to have a rectangular cross section.

According to an embodiment, a control box 863 in which a plurality of electrical components for controlling the operation of the air conditioner are embedded may be disposed on one side of the lower surface of the partitioning portion 860. The control box 863 may be fixed to a lower surface of the partitioning portion 860 adjacent to the drain tray 850.

According to an embodiment, the control box 863 may include a circuit board and a housing disposed to surround the circuit board.

According to an embodiment, the housing of the control box 863 may be formed of the flame-retardant plastic of the disclosure (e.g., flame-retardant plastic formed of the flame-retardant plastic composition of Tables 1 and 2). For example, some components included in the electrical components and/or circuit board disposed inside the housing of the control box 863 may be formed of the flame-retardant plastic. Further, the components included in the indoor unit 800 may be formed of the flame-retardant plastic.

According to an embodiment, as the outer housing of the control box 863 and the electrical components disposed inside the outer housing are formed of flame-retardant plastic, when a fire occurs on the circuit board inside the control box 863, the spread of the fire to the surroundings may be limited.

For example, the flame-retardant plastic composition of the disclosure may limit further spread of fire due to the rapid formation of char when fired.

For example, since the flame-retardant plastic composition of the disclosure does not include a halogen-based material, generation of harmful gases during combustion may be restricted.

According to an embodiment, the flame-retardant plastic composition of the disclosure may achieve eco-friendly management (e.g., ESG management) by including a predetermined proportion of recycled plastic resin.

According to an embodiment, since the flame-retardant plastic composition of the disclosure has substantially the same shrinkage rate as flame-retardant ABS or HIPS, injection-molded products may be prepared using existing manufacturing facilities (e.g., molding devices). As a result, additional costs for manufacturing facilities may be decreased by making injection-molded products formed of the flame-retardant plastic composition using the existing manufacturing facilities.

According to an embodiment, since the flame-retardant plastic composition has a predetermined level of flowability in a molten state, productivity may be enhanced when the flame-retardant plastic composition is injected by the molding device.

FIG. 9 is a perspective view illustrating a refrigerator 900 according to an embodiment of the disclosure.

FIG. 10 is an exploded perspective view illustrating a panel assembly 950 included in a refrigerator 900 according to an embodiment of the disclosure.

The embodiments of FIGS. 9 and 10 may be selectively combined with the embodiments of FIGS. 1 to 3.

Referring to FIGS. 9 and 10, the refrigerator 900 may include a main body 910 forming the overall exterior. A panel assembly 950 and/or a cover case 1000 may be disposed on an upper surface of the main body 910. For example, the panel assembly 950 and/or the cover case 1000 may be disposed on an outer side 911a of an upper surface of the main body 910. The main body 910 may include an external case 911 and an internal case 912. The external case 911 may form the exterior of the refrigerator 900. The external case 911 may be formed in a substantially rectangular parallelepiped shape. The outer case 911 may include an upper surface 911a, a side surface 911b, a rear surface, and a bottom surface. The panel assembly 950 and/or the cover case 1000 may be disposed outside the outer case 911. For example, the cover case 1000 disposed to cover the panel assembly 950 may be provided on an upper wall outer surface 911a of the outer case. The upper surface 911a of the main body 910 may be the upper wall outer surface 911a of the outer case. However, the arrangement or position of the cover case 1000 and the panel assembly 950 is not limited to the example, and they may be provided at various positions such as a lower wall or an outer surface of the outer case 911.

According to an embodiment, the inner case 912 may be provided inside the outer case 911. The inner case 912 may form a storage compartment 30. The inner case 912 may be formed in a substantially rectangular parallelepiped shape.

According to an embodiment, the storage compartment 930 may include a first storage compartment 931 and a second storage compartment 932. The first storage compartment 931 may be a refrigerating compartment 931, and the second storage compartment 932 may be a freezing compartment 932. The refrigerating compartment 931 may be provided above the freezing compartment 932. However, the disclosure is not limited thereto, and the refrigerating compartment 931 may be provided below the freezing compartment 932. The storage compartment 930 may form a space for storing food therein.

According to an embodiment, the storage compartment 930 may include a first storage compartment 931 and a second storage compartment 932. The first storage compartment 931 may be a refrigerating compartment 931, and the second storage compartment 932 may be a freezing compartment 932. The refrigerating compartment 931 may be provided above the freezing compartment 932. However, the disclosure is not limited thereto, and the refrigerating compartment 931 may be provided below the freezing compartment 932. Food may be stored in the storage compartment 930.

According to an embodiment, the refrigerator 900 may include a storage container 933 and a shelf 934. The storage container 933 and the shelf 934 may be disposed in the storage compartment 930. Food may be placed on the shelf 934, and food may be stored in the storage container 933. The number or shape of the shelfs 934 and the storage containers 933 is not limited to the examples illustrated in the drawings.

According to an embodiment, the refrigerator 900 may include a door 920. The door 920 may be rotatably coupled to the main body 910 to open and close the storage compartment 930. The door 920 may include a first door 921 for opening and closing the first storage compartment 931, and a second door 922 for opening and closing the second storage compartment 932. Although only two doors 920 are illustrated, the disclosure is not limited thereto and may be provided with four doors or only one door.

According to an embodiment, the refrigerator 900 may further include a door shelf 923. The door shelf 923 may be coupled to the door 920. The door shelf 923 may be coupled to the door 920 inside the door 920. A storage space 923a capable of storing food may be provided on the door shelf 923. The door shelf 923 may protrude inside the storage compartment 930 when the door 920 closes the storage compartment 930.

According to an embodiment, the refrigerator 900 may further include a hinge 940 and a hinge mounting plate 960.

According to an embodiment, the hinge 940 may couple the door 920 to one side of the main body 910. The hinge 940 may allow the door 920 to be rotatable on the main body 910. The hinge 940 may include a hinge shaft 941 and a hinge coupling plate 942. A portion of the hinge shaft 941 may be inserted into the door. Further, a portion of the hinge shaft 941 may be inserted into the hinge coupling plate 942. The hinge coupling plate 942 may be coupled to the hinge mounting plate 960. The hinge coupling plate 942 may be coupled to the front surface of the hinge mounting plate 960 so that the hinge 940 is coupled to the main body 910.

According to an embodiment, the hinge mounting plate 960 may allow the hinge 940 to be mounted on the main body 910. The hinge mounting plate 960 may be coupled to the main body 910. For example, the hinge mounting plate 960 may be coupled to the upper surface outer side 911a of the main body 910. A plurality of hinge mounting plates 960 may be provided. Accordingly, the hinge 940 and the door 920 may be coupled at one end of the main body 910 in the d1 direction (or −d1 direction). However, the number of hinge mounting plates 960 is not limited as illustrated in the drawings.

According to an embodiment, the refrigerator 900 may include a guide plate 913 and a wire 914.

According to an embodiment, the guide plate 913 may be coupled to the upper wall outer surface 911a of the outer case 911. The guide plate 913 may include a wire hole 913a for guiding the wire 914.

According to an embodiment, the wire 914 may penetrate the wire hole 913a and/or the upper surface of the main body 910. For example, the wire 914 may penetrate the upper portions of the outer case 911 and the inner case 912. The wire 914 may be electrically connected to various devices (e.g., electrical components) provided inside the main body 910. For example, the wire 914 may be electrically connected to the printed circuit board 970 disposed on the upper wall outer surface 911a of the outer case. The guide plate 913 may be disposed on the rear side of the panel assembly 950.

According to an embodiment, a plurality of wires 914 may be provided. The plurality of wires 914 may include a first wire 914a and a second wire 914b. For example, the first wire 914a may be electrically connected to the printed circuit board 970 to control the device inside the main body 910, and the second wire 914b may be electrically connected to the printed circuit board 970 to supply power to the device inside the main body 910. However, the functions of the first wire 914a and the second wire 914b are not limited to the above-described example.

According to an embodiment, the refrigerator 900 may further include a panel assembly 950. The panel assembly 950 may be disposed on the upper wall outer surface 911a of the outer case. For example, the panel assembly 950 may be disposed on the outer upper surface 911a of the outer case. The panel assembly 950 may receive the printed circuit board 970. For example, the printed circuit board 970 on which an electrical component 971 is mounted may be disposed in the panel assembly 950. The panel assembly 950 may be moved in the forward/backward direction on the upper wall outer surface 911a of the outer case 911.

According to an embodiment, the refrigerator 900 may further include a cover case 1000. The cover case 1000 may guide the movement or position of the panel assembly 950 along the forward/backward direction of the main body 910. For example, the panel assembly 950 may be inserted into or withdrawn from the cover case 1000 along the forward/backward direction of the outer case 911. The cover case 1000 may include an upper case 1010 and a lower case 1020.

According to an embodiment, the upper case 1010 may be disposed to cover the lower case 1020 from above the lower case 1020. For example, the upper case 1010 may be disposed to cover the guide plate 913 in which the wire hole 913a is formed. Since the upper case 1010 covers both the lower case 1020 and the guide plate 913, the lower case 1020, the panel assembly 950, the wire 914, and the guide plate 913 may not be visible from outside the refrigerator 900. Therefore, the exterior aesthetics of the refrigerator may be enhanced. However, the upper case 1010 may be omitted.

According to an embodiment, the lower case 1020 may be coupled to the upper wall outer surface 911a of the outer case. The lower case 1020 may receive the panel assembly 950 therein. The lower case 1020 may be disposed under the upper case 1010. For example, the lower case 1020 may be disposed between the upper case 1010 and the outer upper surface 911a of the outer case along the d3 direction (e.g., the height direction or vertical direction of the refrigerator 900). The lower case 1020 may be disposed on the front side of the wire hole 913a. The lower case 1020 may be disposed behind the display 990. For example, the lower case 1020 may be disposed between the display 100 and the wire hole 913a along the d2 direction (e.g., the forward/backward direction of the refrigerator 900). The lower case 1020 may be coupled to the upper wall outer surface 911a of the outer case 911.

According to an embodiment, the refrigerator 900 may further include a display 990. The display 990 may display the operation state of the refrigerator. For example, the display 100 may display the temperature inside the storage compartment. However, the function of the display 990 is not limited to the above-described example. The display 990 may cover the front of the cover case 1000. Therefore, the cover case 1000 and the panel assembly 950 may not be exposed when viewed from the front side of the main body 910. However, the display 990 may be omitted. The display 990 may be coupled to the main body 910. For example, the display 100 may be coupled to the hinge mounting plate 960 to cover the front of the cover case 1000 and the panel assembly 950. The display 990 may include a display portion 991 and a coupling portion 992. The operation state of the refrigerator may be displayed on the display portion 991, and the coupling portion 992 may be coupled to the hinge mounting plate 960. The display portion 991 may be provided between the coupling portions 992. The coupling portions 992 may be provided on two opposite sides of the display portion 991.

According to an embodiment, the components constituting the refrigerator 900 may be composed of flame-retardant plastic of the disclosure (e.g., flame-retardant plastics formed of the flame-retardant plastic composition of Tables 1 and 2). For example, the main body 910 and the upper case 1010 and the lower case 1020 included in the cover case 1000 may be formed of flame-retardant plastic. For example, other exterior and interior components constituting the refrigerator 900 may be formed of flame-retardant plastic.

According to an embodiment, as the components included in the refrigerator 900 are formed of the flame-retardant plastic, when a fire occurs in the panel assembly 950 disposed inside the cover case 1000, it is possible to limit the spread of the fire generated in the control module to the surroundings.

For example, the flame-retardant plastic composition of the disclosure may limit further spread of fire due to the rapid formation of char when fired.

For example, since the flame-retardant plastic composition of the disclosure does not include a halogen-based material, generation of harmful gases during combustion may be restricted.

According to an embodiment, the flame-retardant plastic composition of the disclosure may achieve eco-friendly management (e.g., ESG management) by including a predetermined proportion of recycled plastic resin.

According to an embodiment, since the flame-retardant plastic composition of the disclosure has substantially the same shrinkage rate as flame-retardant ABS or HIPS, injection-molded products may be prepared using existing manufacturing facilities (e.g., molding devices). As a result, additional costs for manufacturing facilities may be decreased by making injection-molded products formed of the flame-retardant plastic composition using the existing manufacturing facilities.

According to an embodiment, since the flame-retardant plastic composition has a predetermined level of flowability in a molten state, productivity may be enhanced when the flame-retardant plastic composition is injected by the molding device.

The flame-retardant plastic composition according to an embodiment of the disclosure relates to a material applicable to exterior and interior components of a home appliance. For example, the flame-retardant plastic composition may be applied to the housing disposed to surround the circuit board of the control box included in the home appliance.

The flame-retardant plastic composition of the disclosure has a predetermined level of flame-retardant and fire-resistant properties, reducing the spread of fire when the fire occurs.

Since the flame-retardant plastic composition of the disclosure does not include a halogen-based material, generation of harmful gases during combustion may be restricted.

The flame-retardant plastic composition of the disclosure may be produced cost-effectively and may have enhanced production efficiency due to its predetermined shrinkage rate.

The flame-retardant plastic composition of the disclosure has a predetermined level of fluidity or greater, allowing for easy injection during the manufacturing process of large-sized components in home appliances.

Effects obtainable from the disclosure are not limited to the above-mentioned effects, and other effects not mentioned may be apparent to one of ordinary skill in the art from the following description.

A home appliance 400, 600, 800, 900 according to an embodiment of the disclosure may comprise a main body 410, 610, 810, 910 forming an exterior, and a control panel 500, 700, 863, 1000 including a printed circuit board 520, 750, 950 disposed inside the main body and a panel housing 510, 730, 910 disposed to surround the printed circuit board 520, 750, 950. The panel housing 510, 730, 910 may be formed of a flame-retardant plastic composition. The flame-retardant plastic composition may include a polypropylene PP-based resin, a recycled plastic resin, a flame retardant including a phosphorus/nitrogen-based compound, and glass fiber. The phosphorus/nitrogen-based compound may include at least one compound among compounds including: a phosphorus/nitrogen-based material, pyrophoric acid, and zinc oxide.

In the home appliance 400, 600, 800, 900 according to an embodiment of the disclosure, the phosphorus/nitrogen-based material may further include at least one compound among compounds including: piperazine pyrophosphate, melamine polyphosphate, ammonium polyphosphate, and alkylamine phosphate.

In the home appliance 400, 600, 800, 900 according to an embodiment of the disclosure, the phosphorus/nitrogen-based compound may be present in an amount of 25 wt % to 35 wt % relative to a total weight of the flame-retardant plastic composition.

In the home appliance 400, 600, 800, 900 according to an embodiment of the disclosure, the pyrophoric acid and the zinc oxide may be present in an amount of 5 wt % to 10 wt % relative to a total weight of the phosphorus/nitrogen-based compound.

In the home appliance 400, 600, 800, 900 according to an embodiment of the disclosure, the glass fiber may be present in an amount of 5 wt % to 15 wt % relative to a total weight of the flame-retardant plastic composition.

In the home appliance 400, 600, 800, 900 according to an embodiment of the disclosure, an average particle diameter of the glass fiber may be 5 μm (micrometer) to 15 μm, and an average length of the glass fiber may be 1 mm to 16 mm.

In the home appliance 400, 600, 800, 900 according to an embodiment of the disclosure, the polypropylene-based resin may be included in an amount of 35 wt % to 55 wt % relative to a total weight of the flame-retardant plastic composition. The polypropylene-based resin may include at least one polymer among polymers including: a propylene homopolymer, an ethylene-propylene random copolymer, and an ethylene-propylene block copolymer.

In the home appliance 400, 600, 800, 900 according to an embodiment of the disclosure, a melt flow index MFI of the polypropylene-based resin may be 5 g/10 min to 50 g/10 min.

In the home appliance 400, 600, 800, 900 according to an embodiment of the disclosure, the recycled plastic resin may include recycled polypropylene and recycled polyethylene. The recycled plastic resin may be present in an amount of 10 wt % to 20 wt % relative to a total weight of the flame-retardant plastic composition.

In the home appliance 400, 600, 800, 900 according to an embodiment of the disclosure, a composition ratio of the recycled polypropylene to the recycled polyethylene included in the recycled plastic resin may be from 10.05 To 10.2.

In the home appliance 400, 600, 800, 900 according to an embodiment of the disclosure, a shrinkage rate of the flame-retardant plastic composition may be 0.3% To 0.8%.

In the home appliance 400, 600, 800, 900 according to an embodiment of the disclosure, an Izod notch impact strength of the flame-retardant plastic composition may be 4.0 Kgf·cm/cm to 4.5 Kgf·cm/cm.

In the home appliance 400, 600, 800, 900 according to an embodiment of the disclosure, a flexural modulus of the flame-retardant plastic composition may be 20,000 kgf/cm² to 27,000 kgf/cm².

In the home appliance 400, 600, 800, 900 according to an embodiment of the disclosure, a tensile strength of the flame-retardant plastic composition may be 240 kgf/cm² to 280 kgf/cm².

In the home appliance 400, 600, 800, 900 according to an embodiment of the disclosure, a melt flow index of the flame-retardant plastic composition may be 5 g/min to 10 g/min.

A washer 400 according to an embodiment of the disclosure may comprise a main body 410 including an inlet formed therein for loading or receiving laundry, a drum rotatably disposed inside the main body, a door 412 hingedly coupled to one side of the main body to open and close the inlet, and a control assembly 500 disposed inside the main body and including a control board 520 including a printed circuit board and a control housing 510 disposed to surround the control board 520. The control housing 510 may be formed of a flame-retardant plastic composition. The flame-retardant plastic composition may include a polypropylene PP-based resin, a recycled plastic resin, a flame retardant including a phosphorus/nitrogen-based compound, and glass fiber. The phosphorus/nitrogen-based compound may include at least one compound among compounds including: a phosphorus/nitrogen-based material, pyrophoric acid, and zinc oxide.

In the washer 400 according to an embodiment of the disclosure, the phosphorus/nitrogen-based material may further include at least one compound among compounds including: piperazine pyrophosphate, melamine polyphosphate, ammonium polyphosphate, or alkylamine phosphate.

In the washer 400 according to an embodiment of the disclosure, the phosphorus/nitrogen-based compound may be present in an amount of 25 wt % to 35 wt % relative to a total weight of the flame-retardant plastic composition.

In the washer 400 according to an embodiment of the disclosure, the pyrophoric acid and the zinc oxide may be present in an amount of 5 wt % to 10 wt % relative to a weight of the phosphorus/nitrogen-based compound.

In the washer 400 according to an embodiment of the disclosure, the glass fiber may be present in an amount of 5 wt % to 20 wt % relative to a total weight of the flame-retardant plastic composition.

In the washer 400 according to an embodiment of the disclosure, an average particle diameter of the glass fiber may be 5 μm (micrometer) to 15 μm, and an average length of the glass fiber may be 1 mm to 16 mm.

1. A home appliance comprising:
a main body forming an exterior; and
a control panel connected to the main body, and including a printed circuit board and a panel housing surrounding at least a portion of the printed circuit board,
wherein the panel housing includes a flame-retardant plastic composition including:
a polypropylene-based resin,
a recycled plastic resin,
a flame retardant including a compound including phosphorus and nitrogen and further including at least one compound from among compounds including pyrophoric acid, or zinc oxide, and
glass fiber.

2. The home appliance of claim 1, wherein the compound including phosphorus and nitrogen further includes at least one compound from among compounds including piperazine pyrophosphate, melamine polyphosphate, ammonium polyphosphate, and alkylamine phosphate.

3. The home appliance of claim 1, wherein the flame-retardant plastic composition further includes 25 wt % to 35 wt % of the compound including phosphorus and nitrogen relative to a total weight of the flame-retardant plastic composition.

4. The home appliance of claim 1, wherein the flame retardant further includes 5 wt % to 10 wt % of a combination of the pyrophoric acid and the zinc oxide relative to a total weight of the flame retardant.

5. The home appliance of claim 1, wherein the flame-retardant plastic composition further includes 5 wt % to 15 wt % of the glass fiber relative to a total weight of the flame-retardant plastic composition.

6. The home appliance of claim 5, wherein the glass fiber includes fibers having an average particle diameter of 5 μm (micrometer) to 15 μm and an average length of 1 mm to 16 mm.

7. The home appliance of claim 1, wherein the flame-retardant plastic composition further includes 35 wt % to 55 wt % of the polypropylene-based resin relative to a total weight of the flame-retardant plastic composition, and
wherein the polypropylene-based resin includes at least one polymer from among polymers including a propylene homopolymer, an ethylene-propylene random copolymer, and an ethylene-propylene block copolymer.

8. The home appliance of claim 7, wherein the polypropylene-based resin has a melt flow index of 5 g/10 min to 50 g/10 min.

9. The home appliance of claim 1, wherein the recycled plastic resin includes recycled polypropylene and recycled polyethylene, and
wherein the flame-retardant plastic composition further includes 10 wt % to 20 wt % of the recycled plastic resin relative to a total weight of the flame-retardant plastic composition.

10. The home appliance of claim 9, wherein the recycled plastic resin further includes a composition ratio of the recycled polypropylene to the recycled polyethylene of 1:0.05 to 1:0.2.

11. The home appliance of claim 1, wherein the flame-retardant plastic composition has a shrinkage rate of 0.3% to 0.8%.

12. The home appliance of claim 1, wherein the flame-retardant plastic composition has an Izod notch impact strength of 4.0 kgf·cm/cm to 4.5 kgf·cm/cm.

13. The home appliance of claim 1, wherein the flame-retardant plastic composition has a flexural modulus of 20,000 kgf/cm² to 27,000 kgf/cm².

14. The home appliance of claim 1, wherein the flame-retardant plastic composition has a tensile strength of 240 kgf/cm² to 280 kgf/cm².

15. The home appliance of claim 1, wherein the flame-retardant plastic composition has a melt flow index of 5 g/min to 10 g/min.

16. A washer comprising:
a main body including an inlet configured to receive laundry;
a rotatable drum inside the main body;
a door configured to open and close the inlet; and
a control assembly connected to the main body and including a control board, the control board including a printed circuit board and a control housing surrounding at least a portion of the control board,
wherein the control housing includes a flame-retardant plastic composition including:
a polypropylene-based resin,
a recycled plastic resin,
a flame retardant including a compound including phosphorus and nitrogen and further including at least one compound from among compounds including pyrophoric acid, or zinc oxide, and
glass fiber.

17. The washer of claim 16, wherein the compound including phosphorus and nitrogen further includes at least one compound from among compounds including piperazine pyrophosphate, melamine polyphosphate, ammonium polyphosphate, and alkylamine phosphate.

18. The washer of claim 16, wherein the flame-retardant plastic composition further includes 25 wt % to 35 wt % of the compound including phosphorus and nitrogen relative to a total weight of the flame-retardant plastic composition.

19. The washer of claim 16, wherein the flame retardant further includes 5 wt % to 10 wt % of a combination of the pyrophoric acid and the zinc oxide relative to a total weight of the flame retardant.

20. The washer of claim 16, wherein the flame-retardant plastic composition further includes 5 wt % to 20 wt % of the glass fiber relative to a total weight of the flame-retardant plastic composition.
